(19) United States
(12) Patent Application Publication
(10) Pub. No.: US 2011/0168240 A1
(43) Pub. Date: Jul. 14, 2011

(54) TRANSLUCENT COVER FOR SOLAR CELLS

(76) Inventor: Earl David Forrest, Asheboro, NC (US)

(21) Appl. No.: 12/687,144

(22) Filed: Jan. 14, 2010

(51) Int. Cl. H01L 31/00

(52) U.S. Cl. 136/252

(57) ABSTRACT

An energy harvesting system includes at least one solar cell operable to harvest solar energy, and a translucent cover concealing the solar cell. The translucent cover exhibits a haze of at least 80% and a light transmission efficiency of at least 70%.

### BACKGROUND OF THE INVENTION

This disclosure relates to solar cells, and more particularly to a cover for solar cells.

Solar panels have been used to generate electricity from light. Solar panels include a plurality of individual solar cells, also known as “photovoltaic cells.” Solar cells have been used on roofs of buildings, in part because that a rooftop location provides maximum exposure to sunlight, and in part because the unsightly appearance of solar cells would widely be considered unacceptable within a building such as a home or office. Concealing a solar cell for indoor use has previously not been feasible due to the severe decrease in efficiency that would occur if a solar cell was concealed.

### SUMMARY OF THE INVENTION

An energy harvesting system includes at least one solar cell operable to harvest solar energy, and a translucent cover concealing the solar cell. The translucent cover exhibits a haze of at least 80% and a light transmission efficiency of at least 70%.

A method of harvesting solar energy includes securing at least one solar cell to a support member, concealing the at least one solar cell with a translucent cover, and harvesting solar energy from light passing through the translucent cover. The translucent cover exhibits a haze of at least 80% and a light transmission efficiency of at least 70%.

These and other features of the present invention can be best understood from the following specification and drawings, the following of which is a brief description.

### BRIEF DESCRIPTION OF THE DRAWINGS

FIG. 1a illustrates an energy harvesting system including at least one solar cell concealed by a translucent cover.

FIG. 1b illustrates another view of the energy harvesting system of FIG. 1a.

FIG. 2 schematically illustrates an energy harvesting system.

FIG. 3a illustrates an implementation of the energy harvesting system of FIG. 2.

FIG. 3b illustrates another view of the energy harvesting system of FIG. 3a.

### DETAILED DESCRIPTION OF THE PREFERRED EMBODIMENT

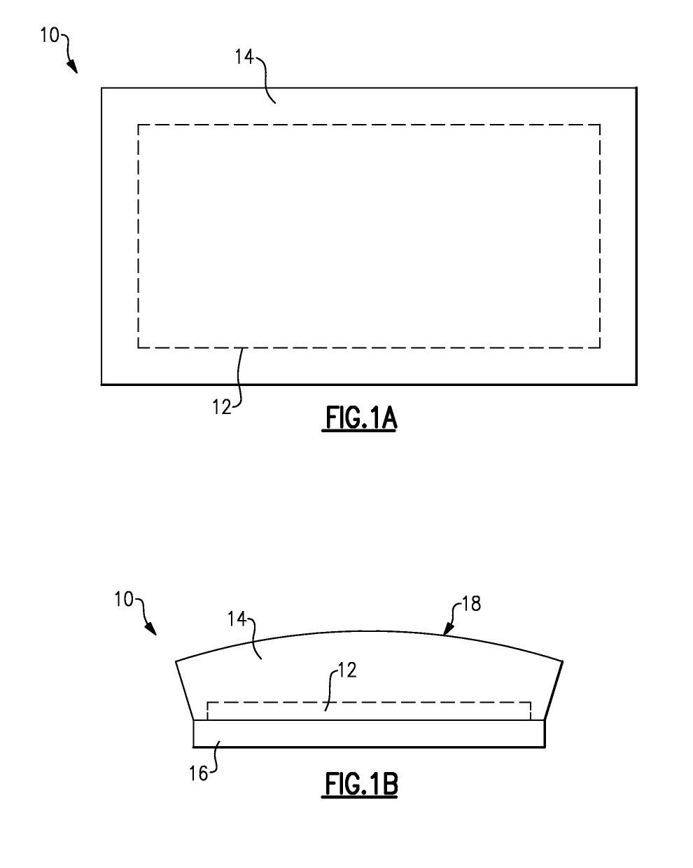

FIGS. 1a-b illustrates an energy harvesting system 10 that includes at least one solar cell 12 concealed by a translucent cover 14. As shown in FIG. 1b, a support member 16 may be used to secure the at least one solar cell 12. In one example, the translucent cover 14 forms a snap fit connection with the support member 16. Of course, other fastening configurations would be possible. As shown in FIG. 1b, an outward-facing portion 18 of the translucent cover 14 may have an arcuate cross section. Of course, the outward-facing portion 18 does not need to be arcuate, and could be planar, for example.

There are competing objectives for the translucent cover 14, as a maximum amount of light efficiency is desired to allow the at least one solar cell 12 to operate efficiently, and at maximum amount of light diffusion is desired to obscure the at least one solar cell 12 so as to hide its appearance beneath the translucent cover 14. Concealing the solar cell 12 with conventional materials such as perforated metals, sheer fabrics, and semi-transparent plastics could conceal the solar cell 12. However, by doing so the efficiency of the solar cell 12 would be significantly reduced in direct proportion to the amount of available light, rendering the solar cell largely ineffective. One could feasibly compensate for this loss in efficiency tends by making the solar cell 12 and its cover 14 larger, however this would be a very costly solution.

To address the conflicting needs for diffusion and light transmission efficiency, the translucent cover 14 is composed of a material exhibiting a haze of at least 80% and a light transmission efficiency of at least 70% such that the translucent cover 14 diffuses light to conceal the solar cell 12, but still enables the solar cell 12 to collect a sufficient amount of light to power a load. Example materials exhibiting these properties include Makrolon® 2407-021065, Makrolon® 2407-021066, Makrolon® 2407-021067, Makrolon® 2407-021068, RTP 1899 X 114729 SC26696, or RTP 1899 X 114729 SC26697. Of course, other materials could be used.

The ASTM D1003 “Standard Test Method for Haze and Luminous Transmittance of Transparent Plastics” defines “haze” as “(1) in transmission, the scattering of light by a specimen responsible for the reduction in contrast of objects viewed through it; (2) the percent of transmitted light that is scattered so that its direction deviates more than a specified angle from the direction of the incident beam.” ASTM D1003 also outlines methods for testing the haze of a material.

Light transmission efficiency may be measured by using a device, such as a luxmeter, to measure an amount of light on a first side of the cover 14, and to measure an amount of light on a second side of the cover 14, and by comparing those amounts. Thus, if there were 100 lumens on a first side of the cover, and 85 lumens on a second side of the cover, the cover 14 would reduce light by 15%, and would have a light transmission efficiency of 85%.

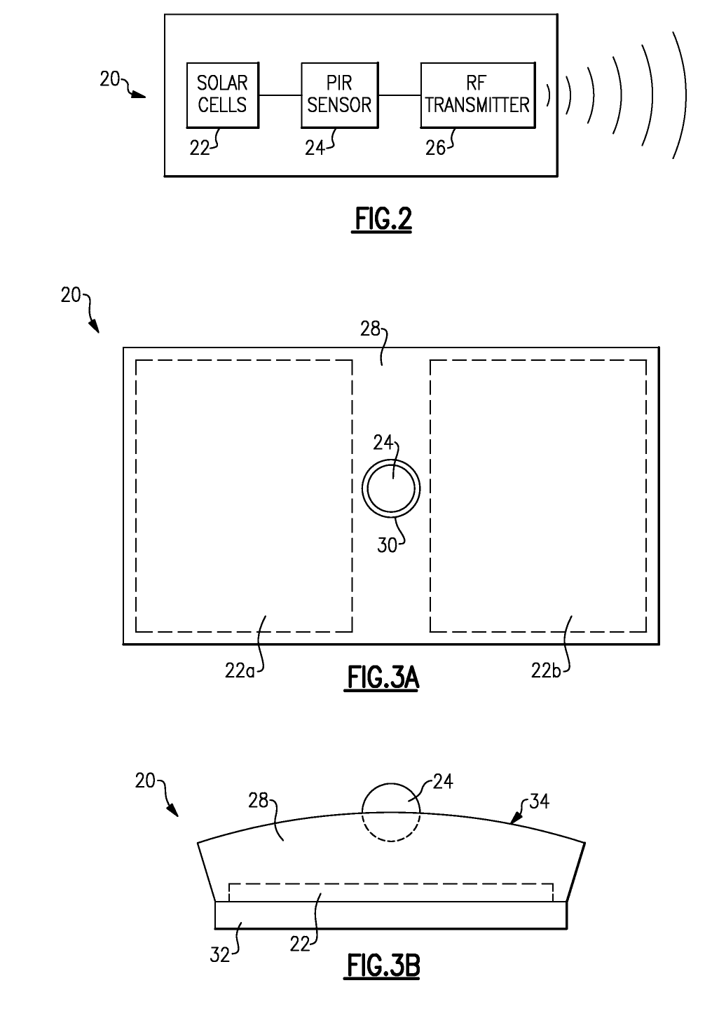

FIG. 2 schematically illustrates an energy harvesting system 20 that includes solar cells 22, a motion sensor 24, and a radio frequency (“RF”) transmitter 26. The solar cells 22 are operable to harvest thermal energy to power the motion sensor 24 (e.g. a passive infrared or “PIR” sensor), which then may cause the RF transmitter 26 to transmit a wireless signal in response to the motion sensor 24 detecting motion. Of course, wireless functionality would not be required, and wired applications would be possible. The system 20 could be used, for example, to turn lights ON in a residential or commercial building.

FIGS. 3a-b illustrate a translucent cover 28 for the energy harvesting system 10 of FIG. 2. The translucent cover 28 includes an aperture 30, through which the motion sensor 24 partially extends. As discussed above, the motion sensor 24 may be a PIR sensor. Of course, other sensors could be used.

As shown in FIG. 3b, a support member 32 may be used to secures the solar cells 22a-b and motion sensor 24 in place. In one example the translucent cover 28 forms a snap fit connection with the support member 32. Of course, other fastening configurations would be possible. As shown in FIG. 3b, an outward-facing portion 34 of the translucent cover 28 may have an arcuate cross section. Of course, the outward-facing portion 34 does not need to be arcuate, and could be planar, for example.

By effectively concealing the solar cells 12, 22, the translucent cover 14, 28 is able to provide an aesthetic effect that was unavailable until now, and is able to provide a protective feature to prevent objects from contacting the solar cells 12, 22, while simultaneously permitting a sufficient quantity of diffuse light to reach the solar cells 12, 22 to enable those solar cells to power their respective loads. This enables the solar cells to be contained within aesthetically pleasing decorative components of a living space, and could lead to a great expansion of the use of solar cells within homes, and not merely on rooftops as they have historically been used.

Although the load of the solar cells 22 has been described as a motion sensor 24 and an RF transmitter 26, it is understood that these are only examples, and that many other types of loads could be powered by a solar cell concealed by a translucent cover having the described properties of exhibiting a haze of at least 80% and a light transmission efficiency of at least 70%.

Although embodiments of this invention have been disclosed, a worker of ordinary skill in this art would recognize that certain modifications would come within the scope of this invention. For that reason, the following claims should be studied to determine the true scope and content of this invention.

What is claimed is:

1. An energy harvesting system, comprising:
at least one solar cell operable to harvest solar energy; and
a translucent cover concealing the solar cell, the translucent cover exhibiting a haze of at least 80% and a light transmission efficiency of at least 70%.

2. The energy harvesting system of claim 1, wherein the translucent cover is at least partially composed of at least one of Makrolon® 2407-021066, RTP 1899 X 114729 SC26696, or RTP 1899 X 114729 SC26697.

3. The energy harvesting system of claim 1, wherein the translucent cover has an arcuate cross section.

4. The energy harvesting system of claim 1, including:
a motion sensor that extends through an aperture in the translucent cover, the motion sensor being powered by the at least one solar cell; and
a transmitter operable to transmit a signal indicating detected motion in response to receiving a signal from the motion sensor.

5. The energy harvesting system of claim 4, wherein the transmitter wirelessly transmits the signal indicating detected motion.

6. The energy harvesting system of claim 4, wherein the translucent cover conceals the at least one solar cell while still permitting a sufficient quantity of light to reach the at least one solar cell such that the at least one solar cell is operable to provide a sufficient amount of voltage to operate the motion sensor.

7. The energy harvesting system of claim 4, including:
a support member that secures the at least one solar cell and the motion sensor, wherein the translucent cover forms a snap fit connection with the support member.

8. The energy harvesting system of claim 7, wherein the support member is secured to at least one of a wall or a ceiling within a building.

9. A method of harvesting solar energy, comprising:
securing at least one solar cell to a support member;
concealing the at least one solar cell with a translucent cover, the translucent cover exhibiting a haze of at least 80% and a light transmission efficiency of at least 70%; and
harvesting solar energy from light passing through the translucent cover.

10. The method of claim 9, including:
at least partially extending a motion sensor through an aperture in the translucent cover;
powering the motion sensor using energy harvested by the at least one solar cell; and
transmitting a signal indicating detected motion in response to receiving a signal from the motion sensor.

11. The method of claim 9, including:
securing the support member to at least one of one of a wall or a ceiling within a building.

12. The method of claim 9, wherein the translucent cover is at least partially composed of at least one of Makrolon® 2407-021066, RTP 1899 X 114729 SC26696, or RTP 1899 X 114729 SC26697.
